(19) United States
(12) Patent Application Publication
(10) Pub. No.: US 2013/0149647 A1
(43) Pub. Date: Jun. 13, 2013

(54) HOLDING APPARATUS, DRAWING APPARATUS, AND METHOD OF MANUFACTURING ARTICLE

(71) Applicant: Canon Kabushiki Kaisha, Tokyo (JP)

(72) Inventors: Yuji Maehara, Saitama-shi (JP); Shigeo Koya, Utsunomiya-shi (JP); Hiroshi Kii, Utsunomiya-shi (JP)

(73) Assignee: CANON KABUSHIKI KAISHA, Tokyo (JP)

(21) Appl. No.: 13/711,401

(22) Filed: Dec. 11, 2012

(30) Foreign Application Priority Data
Dec. 13, 2011 (JP) 2011-272505

(51) Int. Cl. H01L 21/683; G21K 5/08

(52) U.S. Cl. CPC H01L 21/683; G21K 5/08
USPC 430/296; 250/492.3; 269/20

(57) ABSTRACT

A holding apparatus holds a substrate. The apparatus includes a base having burls that support the substrate, a pool whose capacity is variable and from which a liquid is to be supplied into a gap between the base and the substrate supported by the burls, and a regulator configured to regulate the capacity of the pool.

### BACKGROUND OF THE INVENTION

1. Field of the Invention

The present invention relates to a holding apparatus that holds a substrate.

2. Description of the Related Art

Extreme-ultraviolet (EUV) exposure apparatuses and electron-beam exposure (drawing) apparatuses that have been under development as next-generation semiconductor exposure apparatuses perform exposure on substrates in vacuums. In a vacuum, heat transfer caused by convection does not occur, and heat therefore tends to be accumulated in an object. Hence, it is important in the development of the above exposure apparatuses to provide measures for dealing with heat (measures for cooling the object).

In a case where a substrate to be subjected to exposure is cooled, a method is employed in which heat transfer from the substrate to a substrate holding member (hereinafter also simply referred to as holding member) is promoted by using a gas contained between the substrate and the holding member. In a substrate holding apparatus (hereinafter also simply referred to as holding apparatus) disclosed by International Publication No. 2009/011574, since an enhanced promotion of heat transfer is desired for improvement of resolving power and overlay precision, a liquid is contained between a substrate and a holding member, whereby the substrate is held on the holding member. Specifically, a layer of the liquid has a negative pressure, as a capillary pressure of the liquid, with respect to a vacuum atmosphere. This phenomenon is utilized in holding the substrate on the holding member.

In the holding apparatus disclosed by International Publication No. 2009/011574, since the liquid evaporates quickly in a vacuum, the force for holding the substrate is reduced with the quick evaporation of the liquid. To deal with this problem, in a holding apparatus disclosed by International Publication No. 2010/094800, a holding member is provided with grooves having different depths, whereby the holding force at a necessary level is maintained for a longer period of time.

In the holding apparatus disclosed by International Publication No. 2010/094800, the area of a portion of the gap between the substrate and the holding member in which no liquid is present increases with time because of the evaporation of the liquid. Hence, necessary heat transfer may not occur in some areas, and the substrate may undergo thermal deformation.

### SUMMARY OF THE INVENTION

The present invention provides, for example, a holding apparatus advantageous in heat transfer between a substrate and a holding member.

According to one aspect of the present invention, there is provided a holding apparatus that holds a substrate. The apparatus includes a base having burls that support the substrate, a pool whose capacity is variable and from which a liquid is to be supplied into a gap between the base and the substrate supported by the burls, and a regulator configured to regulate the capacity of the pool.

Further features of the present invention will become apparent from the following description of exemplary embodiments with reference to the attached drawings.

### BRIEF DESCRIPTION OF THE DRAWINGS

FIG. 1 illustrates an exemplary substrate holding apparatus according to a first embodiment of the present invention.

FIG. 2 illustrates an exemplary substrate holding apparatus according to a second embodiment of the present invention.

FIG. 3 illustrates an exemplary drawing apparatus according to either of the embodiments of the present invention.

FIG. 4 illustrates a modification of the substrate holding apparatus according to either of the embodiments of the present invention.

FIG. 5 illustrates another modification of the substrate holding apparatus according to either of the embodiments of the present invention.

### DESCRIPTION OF THE EMBODIMENTS

Embodiments of the present invention will now be described with reference to the attached drawings. Basically, like elements are denoted by like reference numerals in all the drawings, and redundant description thereof is omitted.

### First Embodiment

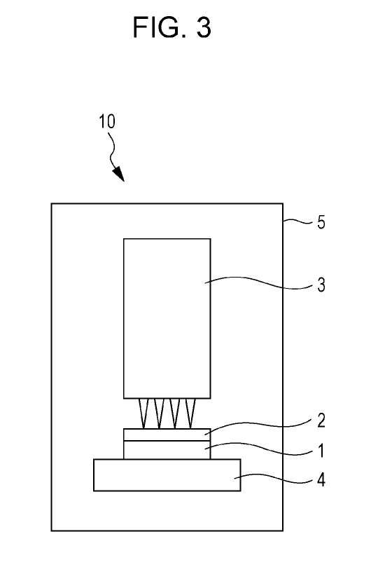

The substrate holding apparatus according to the present invention is applicable to a drawing apparatus that performs drawing on a substrate with a charged particle beam, as described below, and to a wide variety of other apparatuses. FIG. 3 illustrates a drawing apparatus 10 according to either of the following embodiments of the present invention. The drawing apparatus 10 described herein employs an electron beam as a charged particle beam. The drawing apparatus 10 may alternatively employ any of other charged particle beams such as an ion beam. The drawing apparatus 10 includes a vacuum chamber 5, an electron optical system 3, and a stage 4. The electron optical system 3 and the stage 4 are housed in the vacuum chamber 5. The drawing apparatus 10 performs drawing on a substrate 2 with an electron beam and in a vacuum. The stage 4 is movable and positions the substrate 2 with respect to the electron optical system 3. The stage 4 includes a substrate holding apparatus 1 (hereinafter also simply referred to as holding apparatus) that holds the substrate 2.

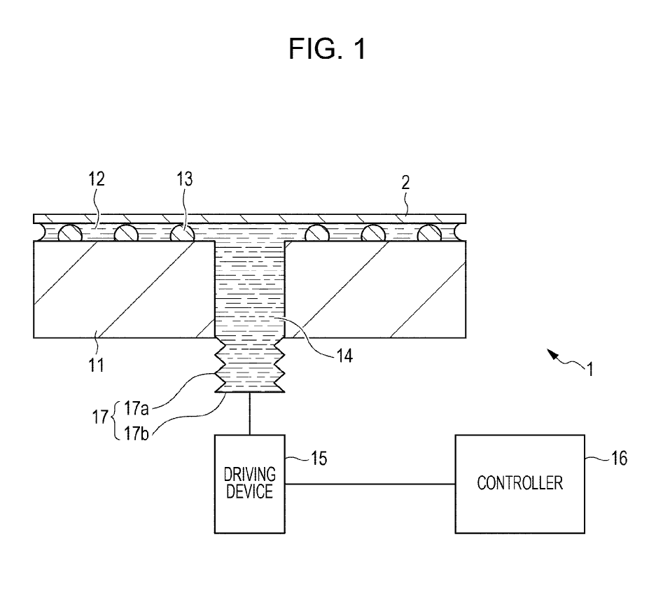

FIG. 1 illustrates a substrate holding apparatus 1 according to a first embodiment of the present invention. The substrate holding apparatus 1 includes a base 11 having burls 13 (supporting portions) that support the substrate 2, and a supply mechanism (to be described below) that supplies liquid 12 into a gap between the substrate 2 and the base 11. An outward force is applied to the surface of the liquid 12 illustrated in FIG. 1 because of capillarity (the capillary pressure of the liquid 12). Therefore, the substrate 2 is pressed against the base 11 with a pressure (differential pressure) corresponding to the difference between the atmospheric pressure in the vacuum chamber 5 and the pressure of the liquid 12. With the differential pressure, a frictional force is produced between the substrate 2 and the burls 13, whereby the substrate 2 is prevented from sliding and is held on the base 11.

The liquid 12, having a certain thermal conductivity, not only contributes to the generation of a force for holding the substrate 2 but also contributes to the reduction in the thermal deformation of the substrate 2 by conducting heat applied to the substrate 2 during drawing to the base 11. When, however, the liquid 12 evaporates with time and the area of contact between the substrate 2 and the liquid 12 is reduced, the thermal deformation of the substrate 2 increases. To suppress the reduction in the area of contact, the supply mechanism is provided. The supply mechanism supplies the liquid 12 into the gap via a hole 14 provided in a central portion of the base 11. The supply mechanism includes a pool 17, a driving device 15, and a controller 16. The capacity of the pool 17 is variable. The liquid 12 is supplied from the pool 17 into the gap. The driving device 15 changes the capacity of the pool 17. The controller 16 controls the driving device 15. A combination of the driving device 15 and the controller 16 is also referred to as a regulator. The pool 17 includes, for example, a bellows 17a and a bottom plate 17b. The driving device 15 includes, for example, an actuator that moves the bottom plate 17b up and down. The pool 17 is not limited to that described above and only needs to have a variable capacity by, for example, including a cylinder and a piston. The driving device 15 is not limited to that described below and only needs to be capable of driving an element (for example, a piston) of the pool 17 in such a manner as to change the capacity of the pool 17 in cooperation with the pool 17.

In the above configuration, the controller 16 controls the driving device 15 to regulate the capacity of the pool 17 and to supply the liquid 12 stored in the pool 17 into the hole 14 so that the area of contact between the substrate 2 and the liquid 12 is not reduced with the evaporation of the liquid 12. To realize such an operation, the controller 16 controls the operation of the driving device 15 on the basis of elapsed time. For example, the controller 16 stores in advance relationships between different elapsed times and different amounts of evaporation of the liquid 12 (or values representing different instructions to the driving device 15 that correspond to different amounts of evaporation of the liquid 12), and controls the operation of the driving device 15 on the basis of the elapsed time and the relationships.

In the configuration according to the first embodiment, for example, a holding apparatus in which heat is effectively transferred between a substrate and a holding member is provided. Hence, a holding apparatus in which the force for holding the substrate 2 on the base 11 and the shape and size of the substrate 2 are effectively maintained even if the liquid 12 evaporates is provided. Furthermore, a drawing apparatus including such a holding apparatus is provided.

### Second Embodiment

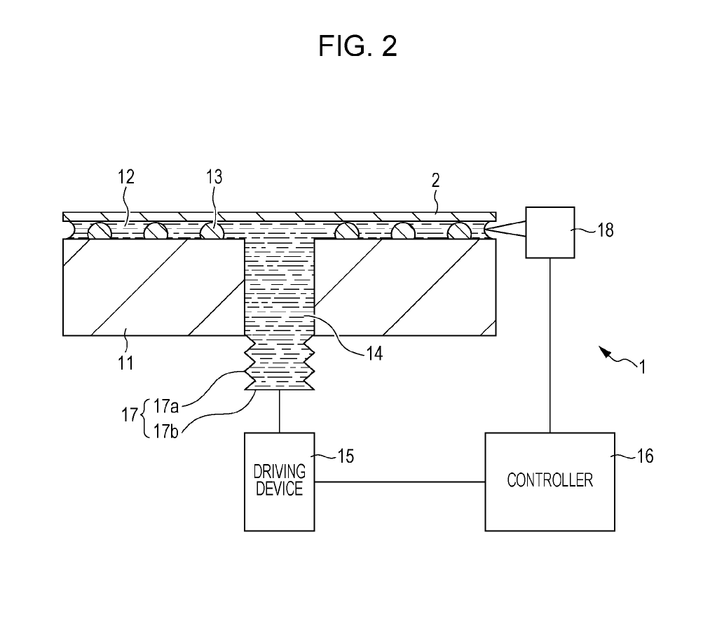

FIG. 2 illustrates a substrate holding apparatus 1 according to a second embodiment of the present invention. The second embodiment differs from the first embodiment in the configuration of the controller 16 and in including a detector 18 illustrated in FIG. 2 that detects the amount of liquid 12 provided in the gap between the substrate 2 and the base 11. The detector 18 detects, for example, the position of a side surface of the liquid 12 in the gap (a surface of the liquid 12 that is in contact with the vacuum atmosphere in the vacuum chamber 5). The controller 16 controls the operation of the driving device 15 on the basis of the output from (the result of detection by) the detector 18 and such that the area of contact between the substrate 2 and the liquid 12 becomes constant. Therefore, for example, the controller 16 may store in advance relationships between different results of detection by the detector 18 and different amounts of liquid 12 in the gap (or values representing different instructions to the driving device 15 that correspond to different amounts of liquid 12), and may control the operation of the driving device 15 on the basis of the relationships.

The detector 18 is not limited to but may be a known length measuring device (length meter) that is capable of measuring the position of the side surface of the liquid 12. For example, an optical length measuring device such as a (length measuring) laser interferometer may be used.

In the configuration according to the second embodiment, for example, a holding apparatus in which heat is effectively transferred between a substrate and a holding member is provided. Hence, a holding apparatus in which the force for holding the substrate 2 on the base 11 and the shape and size of the substrate 2 are effectively maintained even if the liquid 12 evaporates is provided. Furthermore, a drawing apparatus including such a holding apparatus is provided.

### Third Embodiment

A method of manufacturing an article according to a third embodiment of the present invention is suitable for manufacturing articles such as microdevices, including semiconductor devices, and devices having microstructures. The method includes forming a latent pattern in a photoresist on a substrate (performing drawing on a substrate) by using the above drawing apparatus, and developing the latent pattern thus formed on the substrate. The method further includes other known steps (oxidization, film formation, vapor deposition, doping, planarization, etching, resist stripping, dicing, bonding, packaging, and so forth). The method of manufacturing an article according to the third embodiment is superior to known methods in terms of at least one of the performance, the quality, the ease of production, and the costs of production of the article.

While several embodiments of the present invention have been described above, the following exemplary modifications and changes can be made thereto.

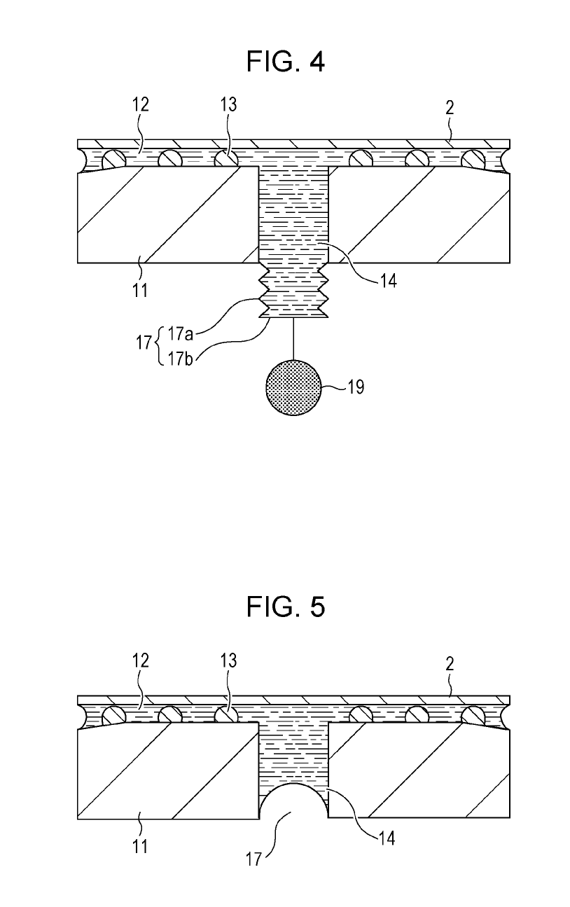

As illustrated in FIG. 4, the top surface of the base 11 (portions of the top surface of the base 11 excluding the burls 13) may be formed such that the distance (gap) between the substrate 2 and the base 11 is reduced from the periphery (peripheral part) thereof toward the center (central part) thereof, or (and) may be surface-treated or processed such that the angle of contact with the liquid 12 is reduced (the lyophilic character (the hydrophilic character if the liquid 12 is water) increases) from the periphery thereof toward the center thereof. If at least one of the foregoing configurations is employed, the capillary pressure of the liquid 12 increases with the reduction in the amount of liquid 12 provided in the gap between the substrate 2 and the base 11. Therefore, if the controller 16 controls the driving device 15 such that the force generated by the driving device 15 becomes constant, the liquid 12 flows from the pool 17 into the gap, whereby the area of contact between the substrate 2 and the liquid 12 is maintained to be constant.

In such a case, the regulator that generates the constant force may be configured as illustrated in FIG. 4, instead of including the driving device 15 and the controller 16. Specifically, the regulator may include a weight 19 that applies a certain force to the bottom plate 17b or the above-mentioned piston (a movable member that defines the capacity of the pool 17). Alternatively, as illustrated in FIG. 5, the pool 17 (a container forming a pool) may have a through hole (or the pool 17 itself may be a through hole). In such a case, the through hole of the pool 17 may be configured such that the capillary pressure of the liquid 12 is constant even if the volume of liquid 12 provided therein changes.

In some of the above configurations, the top surface of the base 11 is configured such that the capillary pressure of the liquid 12 provided in the gap between the substrate 2 and the base 11 increases with the reduction in the amount of liquid 12 in the gap. Furthermore, the regulator is configured such that a force acting in a direction opposite to a direction in which the capillary pressure acts is applied to the surface of the liquid 12 provided in the gap. In other ones of the above configurations, the top surface of the base 11 is configured such that the gap between the base 11 and the substrate 2 or the angle of contact between the substrate 2 and the liquid 12 is reduced from the periphery thereof toward the center thereof. In a case where the liquid 12 is contained in a plurality of dispersed areas defined in the gap between the substrate 2 and the base 11, the top surface of the base 11 may also be configured as described above in each area of the base 11 that is in contact with the liquid 12 provided in the gap.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2011-272505 filed Dec. 13, 2011, which is hereby incorporated by reference herein in its entirety.

What is claimed is:

1. A holding apparatus that holds a substrate, the apparatus comprising:
a base having burls that support the substrate;
a pool whose capacity is variable and from which a liquid is to be supplied into a gap between the base and the substrate supported by the burls; and
a regulator configured to regulate the capacity of the pool.

2. The apparatus according to claim 1, wherein the regulator is configured to regulate the capacity of the pool such that an area of contact between the substrate and the liquid becomes constant.

3. The apparatus according to claim 1, wherein the regulator includes a driving device for changing the capacity of the pool, and a controller configured to control an operation of the driving device based on elapsed time.

4. The apparatus according to claim 1, wherein the regulator includes a detector configured to detect an amount of liquid in the gap, a driving device for changing the capacity of the pool, and a controller configured to control an operation of the driving device based on an output from the detector.

5. The apparatus according to claim 1, wherein a top surface of the base is configured such that capillary pressure of the liquid in the gap increases with reduction in an amount of liquid in the gap, and the regulator is configured to apply a constant force to a surface of the liquid in the gap, the force acting on the surface in a direction opposite to a direction in which the capillary pressure acts on the surface.

6. The apparatus according to claim 5, wherein a portion, to contact with the liquid in the gap, of the top surface of the base is formed such that the gap is reduced from a peripheral part of the portion toward a central part of the portion.

7. The apparatus according to claim 5, wherein a portion, to contact with the liquid in the gap, of the top surface of the base is configured such that an angle of contact of the liquid relative to the top surface is reduced from a peripheral part of the portion toward a central part of the portion.

8. The apparatus according to claim 5, wherein the pool includes a movable member that defines the capacity, and the regulator is configured to apply the constant force to the movable member.

9. The apparatus according to claim 8, wherein the regulator includes a weight that applies a constant gravity thereof to the movable member.

10. The apparatus according to claim 5, wherein the pool has a through hole configured such that a capillary pressure of the liquid therein is constant even if a volume of the liquid therein changes.

11. A drawing apparatus that performs drawing on a substrate with a charged particle beam, the apparatus comprising:
a holding apparatus defined in claim 1 that holds the substrate.

12. A method of manufacturing an article, the method comprising:
performing drawing on a substrate by use of a drawing apparatus;
developing the substrate on which the drawing has been performed; and
processing the developed substrate into the article,
wherein the drawing apparatus performs the drawing on the substrate with a charged particle beam, the apparatus including a holding apparatus that holds the substrate, the holding apparatus including:
a base having burls that support the substrate;
a pool whose capacity is variable and from which a liquid is to be supplied into a gap between the base and the substrate supported by the burls; and
a regulator configured to regulate the capacity of the pool.
